(19) United States
(12) Patent Application Publication
(10) Pub. No.: US 2018/0350415 A1
(43) Pub. Date: Dec. 6, 2018

(54) SEMICONDUCTOR DEVICES AND SEMICONDUCTOR SYSTEMS INCLUDING THE SAME

(71) Applicant: SK hynix Inc., Icheon-si (KR)

(72) Inventor: Young Jun YOON, Icheon-si (KR)

(73) Assignee: SK hynix Inc., Icheon-si (KR)

(21) Appl. No.: 15/804,571

(22) Filed: Nov. 6, 2017

(30) Foreign Application Priority Data
Jun. 1, 2017 (KR) 10-2017-0068503

(51) Int. Cl. G11C 8/18; G06F 3/06

(52) U.S. Cl. CPC G11C 8/18; G06F 3/0679; G06F 3/0659; G06F 3/0611

(57) ABSTRACT

An internal data generation circuit and a semiconductor device including the same may be provided. The internal data generation circuit may include a data alignment circuit configured to align delayed data in synchronization with delayed strobe signals to generate aligned data. The delayed data may be generated by delaying input data in synchronization with internal strobe signals by a predetermined delay time. The delayed strobe signals may be generated by delaying less than all of the internal strobe signals. The internal strobe signals may be generated by dividing a frequency of a strobe signal.

### CROSS-REFERENCE TO RELATED APPLICATION

The present application claims priority under 35 U.S.C 119(a) to Korean Application No. 10-2017-0068503, filed on Jun. 1, 2017, which is incorporated herein by reference in its entirety.

### BACKGROUND

### 1. Technical Field

Embodiments of the present disclosure may generally relate to semiconductor systems, and more particularly to, semiconductor systems including semiconductor devices configured to align data.

### 2. Related Art

As semiconductor systems are developed to operate at high speeds, high data transmission rates (or data communication at high bandwidths) between semiconductor devices included in each semiconductor system have been increasingly in demand. In response to such a demand, various pre-fetch schemes have been proposed. The pre-fetch scheme may correspond to a design technique that latches data inputted in series and outputs the latched data in parallel. A technique for dividing a frequency of a signal may be widely used to obtain the parallel data. If a frequency of a signal is divided to provide the parallel data, a plurality of multi-phase signals having different phases may be generated and the plurality of multi-phase signals may be used in parallelization or serialization of data.

### SUMMARY

According to an embodiment, a semiconductor device may be provided. The semiconductor device may include a data delay circuit, a strobe signal delay circuit, and a data alignment circuit. The data delay circuit may be configured to delay first to fourth input data generated in synchronization with first to fourth internal strobe signals to generate first to fourth delayed data. The first to fourth internal strobe signals may be generated by dividing a frequency of a strobe signal. The strobe signal delay circuit may be configured to delay the second and fourth internal strobe signals to generate a first delayed strobe signal and a second delayed strobe signal. The data alignment circuit may be configured to align the first to fourth delayed data in synchronization with the first and second delayed strobe signals to generate aligned data.

According to an embodiment, a semiconductor device may be provided. The semiconductor device may include a command decoder, an internal data generation circuit, and a memory circuit. The command decoder may be configured to decode a command in synchronization with a clock signal to generate a write enablement signal. The internal data generation circuit may be configured to delay a strobe signal and data including a plurality of bits inputted in series by a predetermined delay time. The internal data generation circuit may be configured to align the delayed data in synchronization with the delayed strobe signal to generate aligned data. The internal data generation circuit may be synchronized with the write enablement signal to generate internal data based on the aligned data. The memory circuit may be configured to store the internal data.

According to an embodiment, a semiconductor system may be provided. The semiconductor system may include a first semiconductor device and a second semiconductor device. The first semiconductor device may be configured to output a command, a clock signal, data, a strobe signal, and a complementary strobe signal. The second semiconductor device may be configured to delay the strobe signal, the complementary strobe signal, and the data based on the command during a write operation. The second semiconductor device may be configured to store the delayed data as internal data in synchronization with the delayed strobe signal and the delayed complementary strobe signal based on the command during the write operation. A delay time of the data may be set to be equal to a delay time of the strobe signal and the complementary strobe signal.

According to an embodiment, an internal data generation circuit may be provided. The internal data generation circuit may include a data alignment circuit configured to align delayed data in synchronization with delayed strobe signals to generate aligned data. The delayed data may be generated by delaying input data in synchronization with internal strobe signals by a predetermined delay time. The delayed strobe signals may be generated by delaying less than all of the internal strobe signals. The internal strobe signals may be generated by dividing a frequency of a strobe signal.

According to an embodiment, the data alignment circuit aligns the delayed data in parallel in synchronization with the delayed strobe signals to generate the aligned data.

According to an embodiment, the predetermined delay time is substantially equal to the delay of the less than all of the internal strobe signals.

According to an embodiment, the internal data generation circuit further comprises a data delay circuit. The data delay circuit configured to delay the input data by the predetermined delay time with a delay circuit for each input data.

According to an embodiment, the internal data generation circuit further comprises a strobe signal delay circuit. The strobe signal delay circuit configured to delay the less than all of the internal strobe signals with a delay circuit for each of the less than all of the internal strobe signals.

According to an embodiment, the data alignment circuit comprises a first latch circuit and second latch circuit. The first latch circuit configured to be synchronized with the delayed strobe signals to latch the delayed data and output the latched delayed data. The second latch circuit configured to be synchronized with input strobe signals to latch the latched delayed data output from the first latch and configured to align the latched delayed data output from the first latch to generate the aligned data.

### BRIEF DESCRIPTION OF THE DRAWINGS

FIG. 1 is a block diagram illustrating a configuration of a semiconductor system according to an embodiment of the present disclosure.

FIG. 2 is a block diagram illustrating a configuration of an internal data generation circuit included in the semiconductor system of FIG. 1.

FIG. 3 is a timing diagram illustrating an operation of an input circuit included in the internal data generation circuit of FIG. 2.

FIG. 4 is a block diagram illustrating a configuration of a data delay circuit included in the internal data generation circuit of FIG. 2.

FIG. 5 is a block diagram illustrating a configuration of a strobe signal delay circuit included in the internal data generation circuit of FIG. 2.

FIG. 6 is a block diagram illustrating a configuration of a data alignment circuit included in the internal data generation circuit of FIG. 2.

FIG. 7 is a timing diagram illustrating an operation of a first latch circuit included in the data alignment circuit of FIG. 6.

FIG. 8 is a block diagram illustrating a configuration of a second latch circuit included in the data alignment circuit of FIG. 6.

FIG. 9 is a block diagram illustrating a configuration of an electronic system employing the semiconductor system described with reference to FIGS. 1 to 8.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

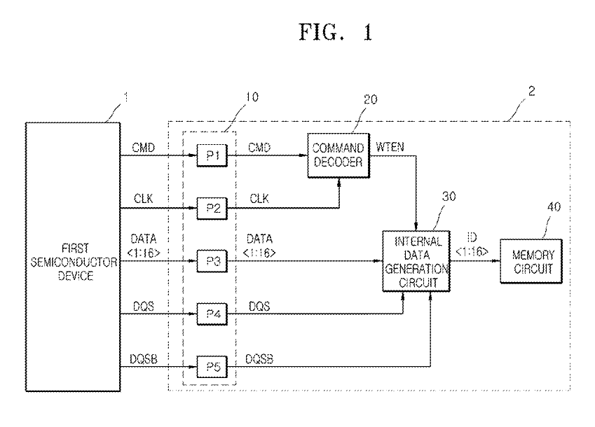

Referring to FIG. 1, a semiconductor system according to an embodiment may include a first semiconductor device 1 and a second semiconductor device 2. The second semiconductor device 2 may include a pad circuit 10, a command decoder 20, an internal data generation circuit 30, and a memory circuit 40.

The first semiconductor device 1 may output a command CMD, a clock signal CLK, first to sixteenth data DATA<1:16>, a strobe signal DQS, and a complementary strobe signal DQSB. Although the command CMD is illustrated like a single signal, the command CMD may be set to include a plurality of bits and may be transmitted through signal lines that transmit at least one group of addresses, commands and data. The first to sixteenth data DATA<1:16> may be transmitted through signal lines that transmit at least one group of addresses, commands and data. The number of bits of the first to sixteenth data DATA<1:16> may be set to be different according to the embodiments. The first to sixteenth data DATA<1:16> may be outputted in series. The clock signal CLK may be a signal which is periodically toggled. The clock signal CLK may be provided to synchronize the second semiconductor device 2 with the first semiconductor device 1. The complementary strobe signal DQSB may be generated to have an opposite phase to the strobe signal DQS. The strobe signal DQS and the complementary strobe signal DQSB may be provided to strobe or synchronize the transfer of the first to sixteenth data DATA<1:16>. Although FIG. 1 illustrates an example in which the strobe signal DQS and the complementary strobe signal DQSB are generated by the first semiconductor device 1, the present disclosure is not limited thereto. For example, in some embodiments, the strobe signal DQS and the complementary strobe signal DQSB may be generated by the second semiconductor device 2. A phase of the clock signal CLK may be different from a phase of the strobe signal DQS.

The pad circuit 10 may include a plurality of pads, for example, five pads P1˜P5. The pads P1˜P5 may be provided to transmit various signals and data for communication between the first and second semiconductor devices 1 and 2. The pads P1˜P5 may be realized using general pads. The number of the pads included in the pad circuit 10 may be set to be different according to the embodiments.

The command decoder 20 may be synchronized with the clock signal CLK inputted through the pad P2 to generate a write enablement signal WTEN according to a level combination of the command CMD inputted through the pad P1. The command decoder 20 may be synchronized with the clock signal CLK inputted through the pad P2 to generate the write enablement signal WTEN which is enabled if a level combination of the command CMD inputted through the pad P1 corresponds to a write operation. The command decoder 20 may decode the command CMD inputted through the pad P1 to generate the write enablement signal WTEN, in synchronization with the clock signal CLK inputted through the pad P2. Although FIG. 1 illustrates an example in which the command decoder 20 generates the write enablement signal WTEN, the present disclosure is not limited thereto. For example, in some embodiments, the command decoder 20 may be realized to generate various signals for controlling various operations of the second semiconductor device 2.

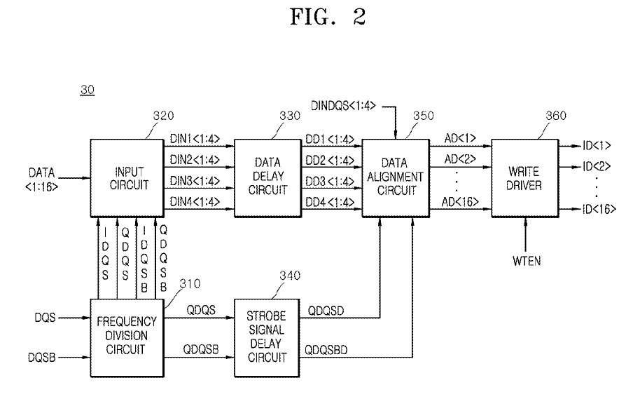

The internal data generation circuit 30 may delay the strobe signal DQS, the complementary strobe signal DQSB, and the first to sixteenth data DATA<1:16> by a predetermined period. The internal data generation circuit 30 may align the delayed first to sixteenth data DATA<1:16> to generate first to sixteenth aligned data (AD<1:16> of FIG. 2), in synchronization with the delayed strobe signal DQS. The internal data generation circuit 30 may be synchronized with the write enablement signal WTEN to generate first to sixteenth internal data ID<1:16> in response to the first to sixteenth aligned data (AD<1:16> of FIG. 2).

The memory circuit 40 may store the first to sixteenth internal data ID<1:16> therein during the write operation. Although FIG. 1 illustrates only an example in which the memory circuit 40 performs the write operation, the present disclosure is not limited thereto. For example, in some embodiments, the memory circuit 40 may also be realized to perform a read operation for outputting the first to sixteenth internal data ID<1:16> stored in the memory circuit 40. The memory circuit 40 may be realized using a general volatile memory circuit or a nonvolatile memory circuit.

As described above, the second semiconductor device 2 may delay the strobe signal DQS, the complementary strobe signal DQSB, and the first to sixteenth data DATA<1:16> by the same period, may align the delayed first to sixteenth data DATA<1:16> in synchronization with the delayed strobe signal DQS and the delayed complementary strobe signal DQSB, and may store the aligned first to sixteenth data DATA<1:16> therein during the write operation. The second semiconductor device 2 may be synchronized with the strobe signal DQS to align the first to sixteenth data DATA<1:16> which are inputted in series and may be synchronized with the clock signal CLK to store the first to sixteenth data DATA<1:16> which are aligned in parallel, during the write operation. The second semiconductor device 2 may perform a domain crossing operation by storing the first to sixteenth data DATA<1:16>, which are inputted in synchronization with the strobe signal DQS, in synchronization with the clock signal CLK during the write operation.

Referring to FIG. 2, the internal data generation circuit 30 may include a frequency division circuit 310, an input circuit 320, a data delay circuit 330, a strobe signal delay circuit 340, a data alignment circuit 350, and a write driver 360.

The frequency division circuit 310 may receive the strobe signal DQS and the complementary strobe signal DQSB to generate a first internal strobe signal IDQS, a second internal strobe signal QDQS, a third internal strobe signal IDQSB and a fourth internal strobe signal QDQSB having a frequency obtained by dividing a frequency of the strobe signal DQS and the complementary strobe signal DQSB. The frequency division circuit 310 may divide a frequency of the strobe signal DQS and the complementary strobe signal DQSB to generate the first to fourth internal strobe signals IDQS, QDQS, IDQSB and QDQSB having different phases. The first to fourth internal strobe signals IDQS, QDQS, IDQSB and QDQSB may be generated to have a phase difference of 90 degrees therebetween. The frequency division circuit 310 may be realized using a general frequency division circuit.

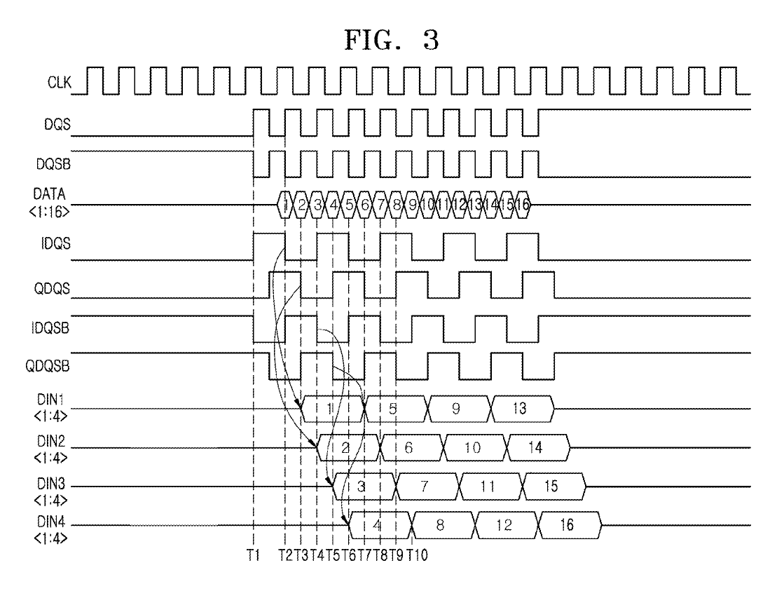

The input circuit 320 may buffer the first to sixteenth data DATA<1:16> to generate a first input data DIN1<1:4>, a second input data DIN2<1:4>, a third input data DIN3<1:4>, and fourth input data DIN4<1:4>, in response to the first to fourth internal strobe signals IDQS, QDQS, IDQSB and QDQSB. The input circuit 320 may buffer the first to sixteenth data DATA<1:16>, which are inputted at points of time that the first to fourth internal strobe signals IDQS, QDQS, IDQSB and QDQSB are generated, to generate the first to fourth input data DIN1<1:4>, DIN2<1:4>, DIN3<1:4> and DIN4<1:4>. An operation for generating the first to fourth input data DIN1<1:4>, DIN2<1:4>, DIN3<1:4> and DIN4<1:4> will be described more fully with reference to FIG. 3 later. The input circuit 320 may be realized using a general buffer circuit.

The data delay circuit 330 may delay the first to fourth input data DIN1<1:4>, DIN2<1:4>, DIN3<1:4> and DIN4<1:4> by a predetermined delay time to generate a first delayed data DD1<1:4>, a second delayed data DD2<1:4>, a third delayed data DD3<1:4>, and a fourth delayed data DD4<1:4>. The predetermined delay time of the data delay circuit 330 may correspond to a parameter ‘tDQSS’ of the second semiconductor device 2. The parameter ‘tDQSS’ denotes a specification of a domain crossing margin between the strobe signal DQS and the clock signal CLK.

The strobe signal delay circuit 340 may delay the second internal strobe signal QDQS and the fourth internal strobe signal QDQSB to generate a first delayed strobe signal QDQSD and a second delayed strobe signal QDQSBD. In some embodiments, the first delayed strobe signal QDQSD and the second delayed strobe signal QDQSBD may be generated by delaying the first internal strobe signal IDQS and the third internal strobe signal IDQSB.

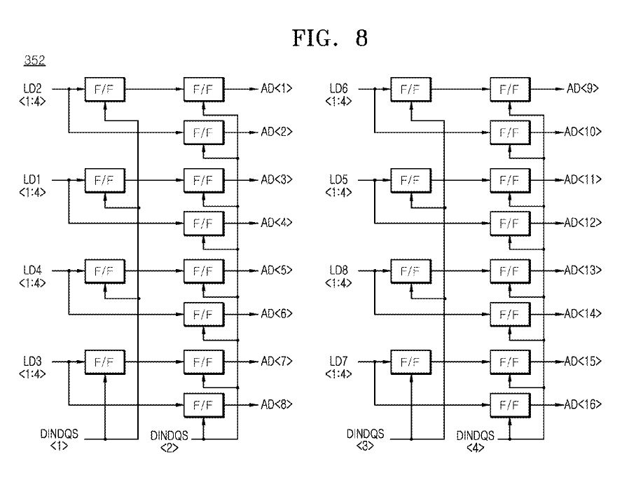

The data alignment circuit 350 may align the first to fourth delayed data DD1<1:4>, DD2<1:4>, DD3<1:4>, and DD4<1:4> in synchronization with the first and second delayed strobe signals QDQSD and QDQSBD to generate the first to sixteenth aligned data AD<1:16>. The data alignment circuit 350 may receive first to fourth input strobe signals DINDQS<1:4>. An operation for generating the first to sixteenth aligned data AD<1:16> will be described with reference to FIG. 8 later.

The write driver 360 may be synchronized with the write enablement signal WTEN to generate the first to sixteenth internal data ID<1:16> from the first to sixteenth aligned data AD<1:16>. The write driver 360 may output the first to sixteenth aligned data AD<1:16> as the first to sixteenth internal data ID<1:16> if the write enablement signal WTEN is enabled.

An operation for buffering the first to sixteenth data DATA<1:16> to generate the first to fourth input data DIN1<1:4>, DIN2<1:4>, DIN3<1:4> and DIN4<1:4>, during the write operation will be described hereinafter with reference to FIG. 3.

At a point of time “T1”, the first semiconductor device 1 may output the strobe signal DQS and the complementary strobe signal DQSB. A period from the point of time “T1” till a point of time “T2” may be set as a preamble period for stabilizing levels of the strobe signal DQS and the complementary strobe signal DQSB.

Meanwhile, the frequency division circuit 310 may receive the strobe signal DQS and the complementary strobe signal DQSB to generate the first to fourth internal strobe signals IDQS, QDQS, IDQSB and QDQSB having a frequency obtained by dividing a frequency of the strobe signal DQS and the complementary strobe signal DQSB. The first to fourth internal strobe signals IDQS, QDQS, IDQSB and QDQSB may be generated to have a phase difference of 90 degrees therebetween.

At the point of time “T2”, the input circuit 320 may be synchronized with a falling edge of the first internal strobe signal IDQS to latch the first datum DATA<1>.

At a point of time “T3”, the input circuit 320 may buffer the latched first datum DATA<1> to generate the first bit datum DIN1<1> of the first input data DIN1<1:4>. The first input data

DIN1<1:4> may be generated in synchronization with the first internal strobe signal IDQS. The input circuit 320 may latch the second datum DATA<2> in synchronization with a falling edge of the second internal strobe signal QDQS.

At a point of time “T4”, the input circuit 320 may buffer the latched second datum DATA<2> to generate the first bit datum DIN2<1> of the second input data DIN2<1:4>. The second input data DIN2<1:4> may be generated in synchronization with the second internal strobe signal QDQS. The input circuit 320 may latch the third datum DATA<3> in synchronization with a falling edge of the third internal strobe signal IDQSB.

At a point of time “T5”, the input circuit 320 may buffer the latched third datum DATA<3> to generate the first bit datum DIN3<1> of the third input data DIN3<1:4>. The third input data DIN3<1:4> may be generated in synchronization with the third internal strobe signal IDQSB. The input circuit 320 may latch the fourth datum DATA<4> in synchronization with a falling edge of the fourth internal strobe signal QDQSB.

At a point of time “T6”, the input circuit 320 may buffer the latched fourth datum DATA<4> to generate the first bit datum DIN4<1> of the fourth input data DIN4<1:4>. The fourth input data DIN4<1:4> may be generated in synchronization with the fourth internal strobe signal QDQSB. The input circuit 320 may latch the fifth datum DATA<5> in synchronization with a falling edge of the first internal strobe signal IDQS.

At a point of time “T7”, the input circuit 320 may buffer the latched fifth datum DATA<5> to generate the second bit datum DIN1<2> of the first input data DIN1<1:4>. The first input data DIN1<1:4> may be generated in synchronization with the first internal strobe signal IDQS. The input circuit 320 may latch the sixth datum DATA<6> in synchronization with a falling edge of the second internal strobe signal QDQS.

At a point of time “T8”, the input circuit 320 may buffer the latched sixth datum DATA<6> to generate the second bit datum DIN2<2> of the second input data DIN2<1:4>. The second input data DIN2<1:4> may be generated in synchronization with the second internal strobe signal QDQS. The input circuit 320 may latch the seventh datum DATA<7> in synchronization with a falling edge of the third internal strobe signal IDQSB.

At a point of time “T9”, the input circuit 320 may buffer the latched seventh datum DATA<7> to generate the second bit datum DIN3<2> of the third input data DIN3<1:4>. The third input data DIN3<1:4> may be generated in synchronization with the third internal strobe signal IDQSB. The input circuit 320 may latch the eighth datum DATA<8> in synchronization with a falling edge of the fourth internal strobe signal QDQSB.

At a point of time “T10”, the input circuit 320 may buffer the latched eighth datum DATA<8> to generate the second bit datum DIN4<2> of the fourth input data DIN4<1:4>. The fourth input data DIN4<1:4> may be generated in synchronization with the fourth internal strobe signal QDQSB.

Operations for generating the remaining bit data DIN1<3:4>, DIN2<3:4>, DIN3<3:4> and DIN4<3:4> of the first to fourth input data DIN1<1:4>, DIN2<1:4>, DIN3<1:4> and DIN4<1:4> may be substantially the same as the operations performed during the periods from the point of time “T1” till the point of time “T10”. Thus, descriptions of the operation for generating the remaining bit data DIN1<3:4>, DIN2<3:4>, DIN3<3:4> and DIN4<3:4> will be omitted hereinafter.

Referring to FIG. 3, the natural numbers of “1” to “16” described in waveforms of the first to fourth input data DIN1<1:4>, DIN2<1:4>, DIN3<1:4> and DIN4<1:4> mean the bit numbers of the first to sixteenth data DATA<1:16> from which the first to fourth input data DIN1<1:4>, DIN2<1:4>, DIN3<1:4> and DIN4<1:4> are generated. For example, the first bit datum DIN1<1> of the first input data DIN1<1:4> denoted by the natural number of “1” may correspond to a datum which is generated from the first bit datum DATA<1> among the first to sixteenth data DATA<1:16>.

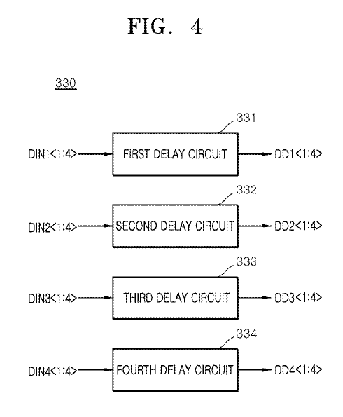

Referring to FIG. 4, the data delay circuit 330 may include a first delay circuit 331, a second delay circuit 332, a third delay circuit 333, and a fourth delay circuit 334.

The first delay circuit 331 may delay the first input data DIN1<1:4> by a predetermined delay time to generate the first delayed data DD1<1:4>. The predetermined delay time of the first delay circuit 331 may be set to correspond to the parameter ‘tDQSS’ that is a specification of the domain crossing margin between the strobe signal DQS and the clock signal CLK, as described above. The first delay circuit 331 may be realized using an inverter chain circuit that is comprised of a plurality of inverters which are coupled in series. Alternatively, the first delay circuit 331 may be realized using a general R-C delay circuit that is comprised of a resistor and a capacitor.

The second delay circuit 332 may delay the second input data DIN2<1:4> by a predetermined delay time to generate the second delayed data DD2<1:4>. The predetermined delay time of the second delay circuit 332 may be set to correspond to the parameter ‘tDQSS’ that is a specification of the domain crossing margin between the strobe signal DQS and the clock signal CLK, as described above. The second delay circuit 332 may be realized using an inverter chain circuit that is comprised of a plurality of inverters which are coupled in series. Alternatively, the second delay circuit 332 may be realized using a general R-C delay circuit that is comprised of a resistor and a capacitor.

The third delay circuit 333 may delay the third input data DIN3<1:4> by a predetermined delay time to generate the third delayed data DD3<1:4>. The predetermined delay time of the third delay circuit 333 may be set to correspond to the parameter ‘tDQSS’ that is a specification of the domain crossing margin between the strobe signal DQS and the clock signal CLK, as described above. The third delay circuit 333 may be realized using an inverter chain circuit that is comprised of a plurality of inverters which are coupled in series. Alternatively, the third delay circuit 333 may be realized using a general R-C delay circuit that is comprised of a resistor and a capacitor.

The fourth delay circuit 334 may delay the fourth input data DIN4<1:4> by a predetermined delay time to generate the fourth delayed data DD4<1:4>. The predetermined delay time of the fourth delay circuit 334 may be set to correspond to the parameter ‘tDQSS’ that is a specification of the domain crossing margin between the strobe signal DQS and the clock signal CLK, as described above. The fourth delay circuit 334 may be realized using an inverter chain circuit that is comprised of a plurality of inverters which are coupled in series. Alternatively, the fourth delay circuit 334 may be realized using a general R-C delay circuit that is comprised of a resistor and a capacitor.

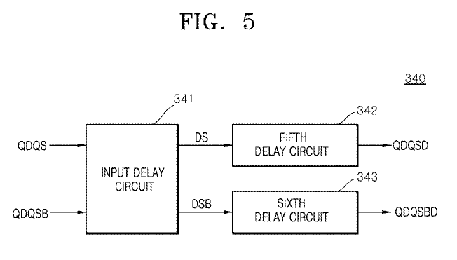

Referring to FIG. 5, the strobe signal delay circuit 340 may include an input delay circuit 341, a fifth delay circuit 342, and a sixth delay circuit 343.

The input delay circuit 341 may delay the second internal strobe signal QDQS by a predetermined delay time to generate a first delayed signal DS. The input delay circuit 341 may delay the fourth internal strobe signal QDQSB by the predetermined delay time to generate a second delayed signal DSB. The predetermined delay time of the input delay circuit 341 may be set to be equal to a delay time of the input circuit 320, which is illustrated in FIG. 2, for buffering the first to sixteenth data DATA<1:16> to generate the first to fourth input data DIN1<1:4>, DIN2<1:4>, DIN3<1:4> and DIN4<1:4>. The input delay circuit 341 may be realized using an inverter chain circuit that is comprised of a plurality of inverters which are coupled in series. Alternatively, the input delay circuit 341 may be realized using a general R-C delay circuit that is comprised of a resistor and a capacitor.

The fifth delay circuit 342 may delay the first delayed signal DS by a predetermined delay time to generate the first delayed strobe signal QDQSD. The predetermined delay time of the fifth delay circuit 342 may be set to correspond to the parameter ‘tDQSS’ that is a specification of the domain crossing margin between the strobe signal DQS and the clock signal CLK, as described above. The fifth delay circuit 342 may be realized using an inverter chain circuit that is comprised of a plurality of inverters which are coupled in series. Alternatively, the fifth delay circuit 342 may be realized using a general R-C delay circuit that is comprised of a resistor and a capacitor.

The sixth delay circuit 343 may delay the second delayed signal DSB by the predetermined delay time to generate the second delayed strobe signal QDQSBD. The predetermined delay time of the sixth delay circuit 343 may be set to correspond to the parameter ‘tDQSS’ that is a specification of the domain crossing margin between the strobe signal DQS and the clock signal CLK, as described above. The sixth delay circuit 343 may be realized using an inverter chain circuit that is comprised of a plurality of inverters which are coupled in series. Alternatively, the sixth delay circuit 343 may be realized using a general R-C delay circuit that is comprised of a resistor and a capacitor.

The first to sixth delay circuits 331, 332, 333, 334, 342 and 343 illustrated in FIGS. 4 and 5 may be designed to have substantially the same delay time.

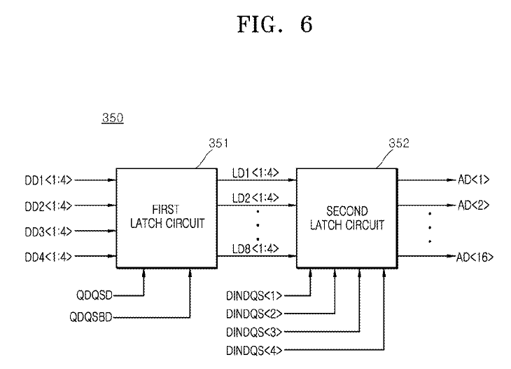

Referring to FIG. 6, the data alignment circuit 350 may include a first latch circuit 351 and a second latch circuit 352.

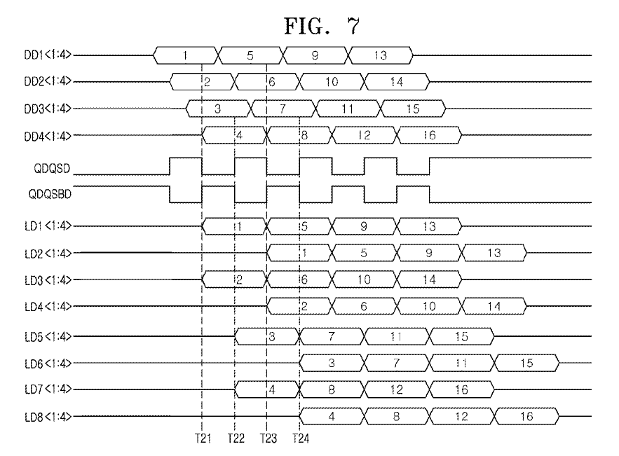

The first latch circuit 351 may latch the first to fourth delayed data DD1<1:4>, DD2<1:4>, DD3<1:4> and DD4<1:4> in synchronization with the first and second delayed strobe signals QDQSD and QDQSBD and may output the latched first to fourth delayed data DD1<1:4>, DD2<1:4>, DD3<1:4> and DD4<1:4> as first to eighth latched data LD1<1:4>, LD2<1:4>, LD3<1:4>, LD4<1:4>, LD5<1:4>, LD6<1:4>, LD7<1:4> and LD8<1:4>. An operation for generating the first to eighth latched data LD1<1:4>, LD2<1:4>, LD3<1:4>, LD4<1:4>, LD5<1:4>, LD6<1:4>, LD7<1:4> and LD8<1:4> from the first to fourth delayed data DD1<1:4>, DD2<1:4>, DD3<1:4> and DD4<1:4> will be described with reference to FIG. 7 later.

The second latch circuit 352 may latch the first to eighth latched data LD1<1:4>, LD2<1:4>, LD3<1:4>, LD4<1:4>,

LD5<1:4>, LD6<1:4>, LD7<1:4> and LD8<1:4> in synchronization with first to fourth input strobe signals DINDQS<1>, DINDQS<2>, DINDQS<3> and DINDQS<4> and may align the latched first to eighth latched data LD1<1:4>, LD2<1:4>, LD3<1:4>, LD4<1:4>, LD5<1:4>, LD6<1:4>, LD7<1:4> and LD8<1:4> to generate the first to sixteenth aligned data AD<1:16>. The first to fourth input strobe signals DINDQS<1:4> may be generated from the strobe signal DQS.

The operation for generating the first to eighth latched data

LD1<1:4>, LD2<1:4>, LD3<1:4>, LD4<1:4>, LD5<1:4>, LD6<1:4>, LD7<1:4> and LD8<1:4> by latching the first to fourth delayed data DD1<1:4>, DD2<1:4>, DD3<1:4> and DD4<1:4> during the write operation will be described hereinafter with reference to FIG. 7.

At a point of time “T21”, the first latch circuit 351 may latch the first bit datum DD1<1> of the first delayed data DD1<1:4> in synchronization with a falling edge of the first delayed strobe signal QDQSD to generate the first bit datum LD1<1> of the first latched data LD1<1:4>. The first latch circuit 351 may latch the first bit datum DD2<1> of the second delayed data DD2<1:4> in synchronization with a falling edge of the first delayed strobe signal QDQSD to generate the first bit datum LD3<1> of the third latched data LD3<1:4>.

At a point of time “T22”, the first latch circuit 351 may latch the first bit datum DD3<1> of the third delayed data DD3<1:4> in synchronization with a falling edge of the second delayed strobe signal QDQSBD to generate the first bit datum LD5<1> of the fifth latched data LD5<1:4>. The first latch circuit 351 may latch the first bit datum DD4<1> of the fourth delayed data DD4<1:4> in synchronization with a falling edge of the second delayed strobe signal QDQSBD to generate the first bit datum LD7<1> of the seventh latched data LD7<1:4>.

At a point of time “T23”, the first latch circuit 351 may latch the second bit datum DD1<2> of the first delayed data DD1<1:4> in synchronization with a falling edge of the first delayed strobe signal QDQSD to generate the second bit datum LD1<2> of the first latched data LD1<1:4>. The first latch circuit 351 may be synchronized with a falling edge of the first delayed strobe signal QDQSD to output the first bit datum LD1<1> of the first latched data LD1<1:4> as the first bit datum LD2<1> of the second latched data LD2<1:4>. The first latch circuit 351 may latch the second bit datum DD2<2> of the second delayed data DD2<1:4> in synchronization with a falling edge of the first delayed strobe signal QDQSD to generate the second bit datum LD3<2> of the third latched data LD3<1:4>. The first latch circuit 351 may be synchronized with a falling edge of the first delayed strobe signal QDQSD to output the first bit datum LD3<1> of the third latched data LD3<1:4> as the first bit datum LD4<1> of the fourth latched data LD4<1:4>.

At a point of time “T24”, the first latch circuit 351 may latch the second bit datum DD3<2> of the third delayed data DD3<1:4> in synchronization with a falling edge of the second delayed strobe signal QDQSBD to generate the second bit datum LD5<2> of the fifth latched data LD5<1:4>. The first latch circuit 351 may be synchronized with a falling edge of the second delayed strobe signal QDQSBD to output the first bit datum LD5<1> of the fifth latched data LD5<1:4> as the first bit datum LD6<1> of the sixth latched data LD6<1:4>. The first latch circuit 351 may latch the second bit datum DD4<2> of the fourth delayed data DD4<1:4> in synchronization with a falling edge of the second delayed strobe signal QDQSBD to generate the second bit datum LD7<2> of the seventh latched data LD7<1:4>. The first latch circuit 351 may be synchronized with a falling edge of the second delayed strobe signal

QDQSBD to output the first bit datum LD7<1> of the seventh latched data LD7<1:4> as the first bit datum LD8<1> of the eighth latched data LD8<1:4>.

Operations for generating the remaining bit data LD1<3:4>, LD2<2:4>, LD3<3:4>, LD4<2:4>, LD5<3:4>, LD6<2:4>, LD7<3:4> and LD8<2:4> of the first to eighth latched data LD1<1:4>, LD2<1:4>, LD3<1:4>, LD4<1:4>, LD5<1:4>, LD6<1:4>, LD7<1:4> and LD8<1:4> may be substantially the same as the operations performed during the periods from the point of time “T21” till the point of time “T24”. Thus, descriptions of the operation for generating the remaining bit data LD1<3:4>, LD2<2:4>, LD3<3:4>, LD4<2:4>, LD5<3:4>, LD6<2:4>, LD7<3:4> and LD8<2:4> will be omitted hereinafter.

In FIG. 7, the natural numbers of “1” to “16” described in waveforms of the first to fourth delayed data DD1<1:4>, DD2<1:4>, DD3<1:4> and DD4<1:4> as well as the first to eighth latched data LD1<1:4>, LD2<1:4>, LD3<1:4>, LD4<1:4>, LD5<1:4>, LD6<1:4>, LD7<1:4> and LD8<1:4> mean the bit numbers of the first to sixteenth data DATA<1:16> from which the first to fourth delayed data DD1<1:4>, DD2<1:4>, DD3<1:4> and DD4<1:4> as well as the first to eighth latched data LD1<1:4>, LD2<1:4>, LD3<1:4>, LD4<1:4>, LD5<1:4>, LD6<1:4>, LD7<1:4> and LD8<1:4> are generated. For example, the first bit datum DD1<1> of the first delayed data DD1<1:4>, the first bit datum LD1<1> of the first latched data LD1<1:4>, and the first bit datum LD2<1> of the second latched data LD2<1:4>, which are denoted by the natural number of “1”, may correspond to data which are generated from the first bit datum DATA<1> among the first to sixteenth data DATA<1:16>.

Referring to FIG. 8, the second latch circuit 352 may be realized using a plurality of flip-flops (F/Fs).

The second latch circuit 352 may latch the first to fourth latched data LD1<1:4>, LD2<1:4>, LD3<1:4> and LD4<1:4> which are inputted at a point of time that the first input strobe signal DINDQS<1> is enabled.

The second latch circuit 352 may output the second latched data LD2<1:4>, which are latched at a point of time that the first input strobe signal DINDQS<1> is enabled, as the first aligned datum AD<1> at a point of time that the second input strobe signal DINDQS<2> is enabled. The second latch circuit 352 may output the first latched data LD1<1:4>, which are latched at a point of time that the first input strobe signal DINDQS<1> is enabled, as the third aligned datum AD<3> at a point of time that the second input strobe signal DINDQS<2> is enabled. The second latch circuit 352 may output the fourth latched data LD4<1:4>, which are latched at a point of time that the first input strobe signal DINDQS<1> is enabled, as the fifth aligned datum AD<5> at a point of time that the second input strobe signal DINDQS<2> is enabled. The second latch circuit 352 may output the third latched data LD3<1:4>, which are latched at a point of time that the first input strobe signal DINDQS<1> is enabled, as the seventh aligned datum AD<7> at a point of time that the second input strobe signal DINDQS<2> is enabled.

The second latch circuit 352 may output the second latched data LD2<1:4>, which are inputted at a point of time that the second input strobe signal DINDQS<2> is enabled, as the second aligned datum AD<2>. The second latch circuit 352 may output the first latched data LD1<1:4>, which are inputted at a point of time that the second input strobe signal DINDQS<2> is enabled, as the fourth aligned datum AD<4>. The second latch circuit 352 may output the fourth latched data LD4<1:4>, which are inputted at a point of time that the second input strobe signal DINDQS<2> is enabled, as the sixth aligned datum AD<6>. The second latch circuit 352 may output the third latched data LD3<1:4>, which are inputted at a point of time that the second input strobe signal DINDQS<2> is enabled, as the eighth aligned datum AD<8>.

The second latch circuit 352 may latch the fifth to eighth latched data LD5<1:4>, LD6<1:4>, LD7<1:4> and LD8<1:4> which are inputted at a point of time that the third input strobe signal DINDQS<3> is enabled.

The second latch circuit 352 may output the sixth latched data LD6<1:4>, which are latched at a point of time that the third input strobe signal DINDQS<3> is enabled, as the ninth aligned datum AD<9> at a point of time that the fourth input strobe signal DINDQS<4> is enabled. The second latch circuit 352 may output the fifth latched data LD5<1:4>, which are latched at a point of time that the third input strobe signal DINDQS<3> is enabled, as the eleventh aligned datum AD<11> at a point of time that the fourth input strobe signal DINDQS<4> is enabled. The second latch circuit 352 may output the eighth latched data LD8<1:4>, which are latched at a point of time that the third input strobe signal DINDQS<3> is enabled, as the thirteenth aligned datum AD<13> at a point of time that the fourth input strobe signal DINDQS<4> is enabled. The second latch circuit 352 may output the seventh latched data LD7<1:4>, which are latched at a point of time that the third input strobe signal DINDQS<3> is enabled, as the fifteenth aligned datum AD<15> at a point of time that the fourth input strobe signal DINDQS<4> is enabled.

The second latch circuit 352 may output the sixth latched data LD6<1:4>, which are inputted at a point of time that the fourth input strobe signal DINDQS<4> is enabled, as the tenth aligned datum AD<10>. The second latch circuit 352 may output the fifth latched data LD5<1:4>, which are inputted at a point of time that the fourth input strobe signal DINDQS<4> is enabled, as the twelfth aligned datum AD<12>. The second latch circuit 352 may output the eighth latched data LD8<1:4>, which are inputted at a point of time that the fourth input strobe signal DINDQS<4> is enabled, as the fourteenth aligned datum AD<14>. The second latch circuit 352 may output the seventh latched data LD7<1:4>, which are inputted at a point of time that the fourth input strobe signal DINDQS<4> is enabled, as the sixteenth aligned datum AD<16>.

As described above, a semiconductor system according to an embodiment may delay data and internal strobe signals having a frequency obtained by dividing a frequency of a strobe signal by a predetermined delay time and may align the delayed data in parallel in synchronization with the delayed internal strobe signals to store the parallelized data therein. In addition, according to the semiconductor system, the number of delay circuits for delaying the data may be reduced by parallelizing the delayed data in synchronization with the delayed internal strobe signals after the data are delayed. Thus, an amount of a toggling current of the data may be reduced by the reduced number of the delay circuits, thereby reducing the power consumption of the semiconductor system while the data are aligned. Moreover, a layout area of the semiconductor system may be reduced by reduction of the number of the delay circuits.

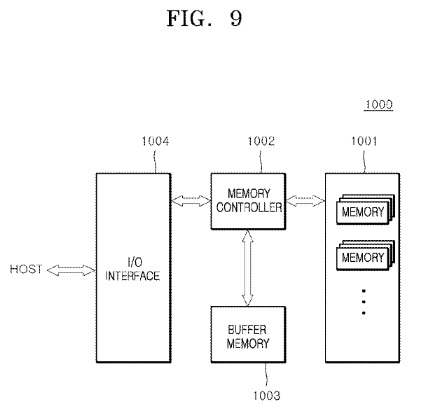

The semiconductor system described with reference to FIGS. 1 to 8 may be applied to an electronic system that includes a memory system, a graphic system, a computing system, a mobile system, or the like. For example, referring to FIG. 9, an electronic system 1000 according an embodiment may include a data storage circuit 1001, a memory controller 1002, a buffer memory 1003, and an input and output (input/output) (I/O) interface 1004.

The data storage circuit 1001 may store data which are outputted from the memory controller 1002 or may read and output the stored data to the memory controller 1002, according to a control signal outputted from the memory controller 1002. The data storage circuit 1001 may include the second semiconductor device 2 illustrated in FIG. 1. The data storage circuit 1001 may include a nonvolatile memory that can retain their stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. The memory controller 1002 may include the first semiconductor device 1 illustrated in FIG. 1. Although FIG. 9 illustrates the memory controller 1002 with a single block, the memory controller 1002 may include one controller for controlling the data storage circuit 1001 comprised of a nonvolatile memory and another controller for controlling the buffer memory 1003 comprised of a volatile memory.

The buffer memory 1003 may temporarily store the data to be processed by the memory controller 1002. That is, the buffer memory 1003 may temporarily store the data which are outputted from or to be inputted to the data storage circuit 1001. The buffer memory 1003 may store the data, which are outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM, or a static random access memory (SRAM).

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data generated from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB) drive, a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE).

The electronic system 1000 may be used as an auxiliary storage device of the host or an external storage device. The electronic system 1000 may include a solid state disk (SSD), a USB drive, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

What is claimed is:

1. A semiconductor device comprising:
a data delay circuit configured to delay first to fourth input data generated in synchronization with first to fourth internal strobe signals to generate first to fourth delayed data, wherein the first to fourth internal strobe signals are generated by dividing a frequency of a strobe signal;
a strobe signal delay circuit configured to delay the second and fourth internal strobe signals to generate a first delayed strobe signal and a second delayed strobe signal; and
a data alignment circuit configured to align the first to fourth delayed data in synchronization with the first and second delayed strobe signals to generate aligned data.

2. The semiconductor device of claim 1, wherein a delay time of the data delay circuit and a delay time of the strobe signal delay circuit are set to be equal to each other.

3. The semiconductor device of claim 1, wherein the aligned data include a plurality of bits which are generated in parallel.

4. The semiconductor device of claim 1, wherein the data delay circuit includes:
a first delay circuit configured to delay the first input data by a predetermined delay time to generate the first delayed data;
a second delay circuit configured to delay the second input data by the predetermined delay time to generate the second delayed data;
a third delay circuit configured to delay the third input data by the predetermined delay time to generate the third delayed data; and
a fourth delay circuit configured to delay the fourth input data by the predetermined delay time to generate the fourth delayed data.

5. The semiconductor device of claim 1, wherein the strobe signal delay circuit includes:
an input delay circuit configured to delay the second and fourth internal strobe signals by a predetermined period to generate a first delayed signal and a second delayed signal;
a fifth delay circuit configured to delay the first delayed signal by a predetermined delay time to generate the first delayed strobe signal; and
a sixth delay circuit configured to delay the second delayed signal by the predetermined delay time to generate the second delayed strobe signal.

6. The semiconductor device of claim 1, wherein the data alignment circuit includes:
a first latch circuit configured to be synchronized with the first and second delayed strobe signals to latch the first to fourth delayed data and configured to output the latched first to fourth delayed data as first to eighth latched data; and
a second latch circuit configured to be synchronized with first to fourth input strobe signals to latch the first to eighth latched data and configured to align the latched first to eighth latched data to generate the aligned data.

7. A semiconductor device comprising:
a command decoder configured to decode a command in synchronization with a clock signal to generate a write enablement signal;
an internal data generation circuit configured to delay a strobe signal and data including a plurality of bits inputted in series by a predetermined delay time, configured to align the delayed data in synchronization with the delayed strobe signal to generate aligned data, and configured to be synchronized with the write enablement signal to generate internal data based on the aligned data; and
a memory circuit configured to store the internal data.

8. The semiconductor device of claim 7,
wherein the aligned data include a plurality of bits which are generated in parallel; and
wherein the internal data include a plurality of bits which are generated in parallel.

9. The semiconductor device of claim 7, wherein the internal data generation circuit includes:
a frequency division circuit configured to divide a frequency of the strobe signal to generate first to fourth internal strobe signals;
an input circuit configured to buffer the data in synchronization with the first to fourth internal strobe signals to generate first to fourth input data;
a data delay circuit configured to delay the first to fourth input data by the predetermined delay time to generate first to fourth delayed data constituting the delayed data;
a strobe signal delay circuit configured to delay the second and fourth internal strobe signals by the predetermined delay time to generate a first delayed strobe signal and a second delayed strobe signal;
a data alignment circuit configured to be synchronized with the first and second delayed strobe signals to latch the first to fourth delayed data and configured to be synchronized with first to fourth input strobe signals to output the latched first to fourth delayed data as the aligned data; and
a write driver configured to be synchronized with the write enablement signal to generate the internal data based on the aligned data.

10. The semiconductor device of claim 9, wherein the first to fourth input strobe signals are generated from the strobe signal.

11. The semiconductor device of claim 9, wherein the predetermined delay time of the data delay circuit and the predetermined delay time of the strobe signal delay circuit are set to be equal to each other.

12. The semiconductor device of claim 9, wherein the data delay circuit includes:
a first delay circuit configured to delay the first input data by the predetermined delay time to generate the first delayed data;
a second delay circuit configured to delay the second input data by the predetermined delay time to generate the second delayed data;
a third delay circuit configured to delay the third input data by the predetermined delay time to generate the third delayed data; and
a fourth delay circuit configured to delay the fourth input data by the predetermined delay time to generate the fourth delayed data.

13. The semiconductor device of claim 9, wherein the strobe signal delay circuit includes:
an input delay circuit configured to delay the second and fourth internal strobe signals by a predetermined period to generate a first delayed signal and a second delayed signal;
a fifth delay circuit configured to delay the first delayed signal by the predetermined delay time to generate the first delayed strobe signal; and
a sixth delay circuit configured to delay the second delayed signal by the predetermined delay time to generate the second delayed strobe signal.

14. The semiconductor device of claim 9, wherein the data alignment circuit includes:
a first latch circuit configured to be synchronized with the first and second delayed strobe signals to latch the first to fourth delayed data and configured to output the latched first to fourth delayed data as first to eighth latched data; and
a second latch circuit configured to be synchronized with the first to fourth input strobe signals to latch the first to eighth latched data and configured to align the latched first to eighth latched data to generate the aligned data.

15. A semiconductor system comprising:
a first semiconductor device configured to output a command, a clock signal, data, a strobe signal, and a complementary strobe signal; and
a second semiconductor device configured to delay the strobe signal, the complementary strobe signal, and the data based on the command during a write operation and configured to store the delayed data as internal data in synchronization with the delayed strobe signal and the delayed complementary strobe signal based on the command during the write operation,
wherein a delay time of the data is set to be equal to a delay time of the strobe signal and the complementary strobe signal.

16. The semiconductor system of claim 15,
wherein the data include a plurality of bits which are outputted in series from the first semiconductor device; and
wherein the internal data include a plurality of bits which are generated in parallel.

17. The semiconductor system of claim 15, wherein the second semiconductor device includes:
a command decoder configured to decode the command in synchronization with the clock signal to generate a write enablement signal;
an internal data generation circuit configured to delay the strobe signal, the complementary strobe signal and the data by a predetermined delay time, configured to align the delayed data to generate aligned data in synchronization with first to fourth internal strobe signals generated from the strobe signal and the complementary strobe signal, and configured to be synchronized with the write enablement signal to generate the internal data based on the aligned data; and
a memory circuit configured to store the internal data.

18. The semiconductor system of claim 17, wherein the internal data generation circuit includes:
a frequency division circuit configured to divide a frequency of the strobe signal to generate the first to fourth internal strobe signals;
an input circuit configured to buffer the data, which are inputted at points of time that the first to fourth internal strobe signals are enabled, to generate first to fourth input data;
a data delay circuit configured to delay the first to fourth input data by the predetermined delay time to generate first to fourth delayed data constituting the delayed data;
a strobe signal delay circuit configured to delay the second and fourth internal strobe signals by the predetermined delay time to generate a first delayed strobe signal and a second delayed strobe signal;
a data alignment circuit configured to be synchronized with the first and second delayed strobe signals to latch the first to fourth delayed data and configured to be synchronized with first to fourth input strobe signals to output the latched first to fourth delayed data as the aligned data; and
a write driver configured to be synchronized with the write enablement signal to generate the internal data based on the aligned data.

19. The semiconductor system of claim 18, wherein the data delay circuit includes:
a first delay circuit configured to delay the first input data by the predetermined delay time to generate the first delayed data;
a second delay circuit configured to delay the second input data by the predetermined delay time to generate the second delayed data;
a third delay circuit configured to delay the third input data by the predetermined delay time to generate the third delayed data; and
a fourth delay circuit configured to delay the fourth input data by the predetermined delay time to generate the fourth delayed data.

20. The semiconductor system of claim 18, wherein the strobe signal delay circuit includes:
an input delay circuit configured to delay the second and fourth internal strobe signals by a predetermined period to generate a first delayed signal and a second delayed signal;
a fifth delay circuit configured to delay the first delayed signal by the predetermined delay time to generate the first delayed strobe signal; and
a sixth delay circuit configured to delay the second delayed signal by the predetermined delay time to generate the second delayed strobe signal.
